(19) United States
(12) Patent Application Publication
(10) Pub. No.: US 2019/0010600 A1
(43) Pub. Date: Jan. 10, 2019

(54) MASK BODY, MASK AND FABRICATION METHOD THEREOF

(71) Applicants: BOE Technology Group Co., Ltd., Beijing (CN); Ordos Yuansheng Optoelectronics Co., Ltd., Ordos, Inner Mongolia (CN)

(72) Inventors: Zhiming LIN, Beijing (CN); Zhen WANG, Beijing (CN); Jian ZHANG, Beijing (CN)

(21) Appl. No.: 15/745,038

(22) PCT Filed: Jul. 3, 2017
(86) PCT No.: PCT/CN2017/091401

§ 371 Date: Jan. 15, 2018

(30) Foreign Application Priority Data
Dec. 26, 2016 (CN) 201611218750.1

(51) Int. Cl. C23C 14/04; C23C 14/24; H01L 51/56; H01L 51/00

(52) U.S. Cl. CPC C23C 14/042; H01L 51/0011; H01L 51/56; C23C 14/24

(57) ABSTRACT

The present disclosure provides a mask body, including at least one mask area and a non-mask area surrounding the at least one mask area. A portion, directly facing the mask area, of an edge extending along a preset stretching direction of the mask body is a curved portion. The curved portion recesses towards the mask area that the curved portion directly faces. Accordingly, the present disclosure further provides a mask and a fabrication method thereof. The present disclosure can alleviate wrinkle phenomenon on both sides of a mask area of a mask.

### CROSS-REFERENCE TO RELATED APPLICATION

This is a National Phase Application filed under 35 U.S.C. 371 as a national stage of PCT/CN2017/091401, filed on Jul. 3, 2017, an application claiming the benefit of priority to China Patent Application No. 201611218750.1 filed on Dec. 26, 2016, the contents of which are incorporated herein in their entirety by reference.

### TECHNICAL FIELD

The present disclosure relates to the field of display apparatus production, and particularly relates to a mask body, a mask and a fabrication method thereof.

### BACKGROUND

At present, in mass production of organic light-emitting diode (OLED) displays, color displays are formed mainly by means of fine metal mask (FMM). Specifically, an organic light-emitting material is deposited on a display backplane according to a predetermined procedure by way of evaporation, and organic materials of various colors are deposited on corresponding positions using a pattern on a mask. To this end, a mask needs to be fabricated first.

### SUMMARY

The present disclosure provides a mask body, including at least one mask area and a non-mask area surrounding the at least one mask area, a portion, directly facing the mask area, of an edge extending along a preset stretching direction of the mask body is a curved portion, and the curved portion recesses towards the mask area that the curved portion directly faces.

Optionally, the preset stretching direction is a length direction or a width direction of the mask body.

Optionally, the curved portion becomes closer to the mask area that the curved portion directly faces, from two ends to the middle of the curved portion in the preset stretching direction.

Optionally, the curved portion is arc-shaped.

Optionally, the curved portion becomes closer, in a stepwise manner, to the mask area that the curved portion directly faces, from two ends to the middle of the curved portion in the preset stretching direction.

Optionally, the at least one mask area is arranged along the preset stretching direction.

Optionally, a size of the mask area in the preset stretching direction is in a range of 100 mm to 120 mm;

a difference between a distance from any one end of the curved portion to the mask area and a distance from the middle of the curved portion to the mask area is in a range of 140 L μm to 160 L μm, and the distance from the middle of the curved portion to the mask area is in a range of 380 μm to 420 μm, where L is a value of shrinkage of the middle of an edge of a reference mask body corresponding to the mask body towards an inner side of the reference mask body when the reference mask body is stretched in the preset stretching direction.

Optionally, the mask body has a length in a range of 800 mm to 900 mm, a width in a range of 80 mm to 100 mm, and a thickness in a range of 20 μm to 40 μm.

Optionally, the preset stretching direction is a length direction of the mask body.

Optionally, a material for forming the mask body includes invar.

Optionally, portions of the non-mask area on both sides of all the mask area in the preset stretching direction each include: two extension parts extending along the preset stretching direction and a connection part connecting between the two extension parts, and the connection part is connected to ends of the extension parts proximal to the mask area.

Accordingly, the present disclosure further provides a method for fabricating a mask, including:

providing a mask body, which is the above mask body provided by the present disclosure; and

applying pulling forces, which are along the preset stretching direction and towards an outer side of the mask body, to two ends of the mask body in the preset stretching direction, respectively.

Optionally, the pulling force applied to each end of the mask body is increased from a value ranging from 1 N to 3 N to a value ranging from 8 N to 12 N, gradually.

Optionally, portions of the non-mask area of the mask body on both sides of all the mask area in the preset stretching direction each include: two extension parts extending along the preset stretching direction and a connection part connecting between the two extension parts, and the pulling force is applied to ends of the extension parts distal to the mask area.

Optionally, the method further includes fixing the stretched mask body to a frame to obtain the mask.

Accordingly, the present disclosure further provides a mask including the above mask body provided by the present disclosure and a frame for mounting the mask body.

### BRIEF DESCRIPTION OF THE DRAWINGS

The accompanying drawings, which serve to provide a further understanding of the present disclosure and constitute a part of this specification, are used for explaining the present disclosure together with the following specific implementations, rather than limiting the present disclosure. In the drawings:

FIG. 1 is a schematic structure diagram of a mask body in a comparative example;

FIG. 2 is a schematic diagram illustrating wrinkle state along A-A′ line of the mask body in FIG. 1 subjected to stretching;

FIG. 3 is a schematic structure diagram of a mask body provided in an embodiment of the present disclosure;

FIG. 4 is a schematic diagram illustrating expansion tendency generated when a mask body provided in an embodiment of the present disclosure is being stretched;

FIG. 5 is a comparison diagram illustrating wrinkle state along A-A′ line of a mask body provided in an embodiment of the present disclosure and subjected to stretching and wrinkle state along A-A′ line of the mask body provided in the comparative example and subjected to stretching; and

FIG. 6 is a schematic diagram illustrating ansys software simulation of a mask body provided in an embodiment of the present disclosure when being stretched.

### DETAILED DESCRIPTION

Specific implementations of the present disclosure will be described in detail below in conjunction with the accompanying drawings. It should be understood that, the specific implementations described herein are merely used for describing and explaining the present disclosure, rather than limiting the present disclosure.

Because a mask has a very thin thickness, in the fabrication process of the mask, pulling forces are generally applied to two ends of a mask body to stretch the mask body after a mask area is formed on the mask body, so as to allow the stretched mask body to have certain strength and maintain a stable shape. However, due to a difference in thickness between the mask area and a non-mask area on both sides of the mask area of the mask body, an edge of the mask body directly facing the mask area shrinks inward during the stretching, which causes wrinkles in the non-mask area of the stretched mask body. The closer to the middle of the mask area in the stretching direction, the more significant the wrinkle phenomenon. If these masks having wrinkles are put into production, the product yield will be affected.

In view of the above, the present disclosure proposes a mask body, a mask and a fabrication method thereof.

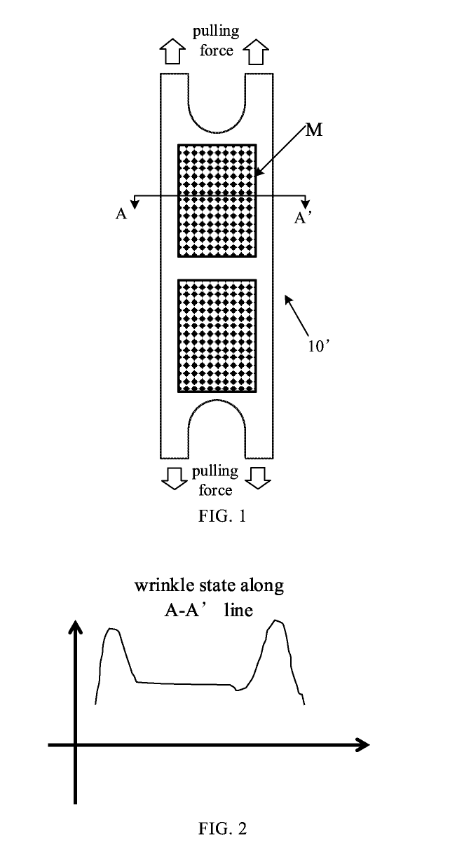

FIG. 1 is a schematic structure diagram of a mask body in a comparative example, and FIG. 2 is a schematic diagram illustrating wrinkle state along A-A′ line of the mask body in FIG. 1 that has been stretched. As shown in FIG. 1, a mask body 10′ includes at least one mask area M and a non-mask area (i.e., a blank area in FIG. 1) surrounding the at least one mask area M, and edges of the non-mask area on both sides of the mask area M are straight. In FIG. 1, the mask body 10′ is subjected to pulling forces in a vertical direction. Two raised parts of a curve in FIG. 2 indicate that obvious wrinkles occur in portions of the non-mask area on both sides of the mask area, and a flat part between the two raised parts indicates that the mask area is flat. Edges of display panels fabricated using the mask body shown in FIG. 1 will suffer from various degrees of vertical Mura.

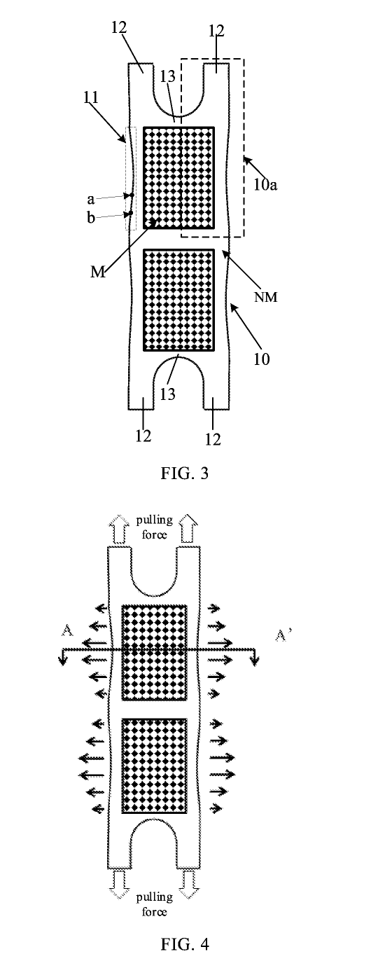

As an aspect of the present disclosure, there is provided a mask body 10, as shown in FIG. 3, including at least one mask area M and a non-mask area NM (i.e., a blank area in FIG. 3) surrounding the at least one mask area M. The mask area M corresponds to a display area of a display substrate. A portion, directly facing the mask area M, of an edge, extending along a preset stretching direction, of the mask body 10 is configured as a curved portion 11. The curved portion 11 recesses towards the mask area M that the curved portion 11 directly faces. The preset stretching direction may be a length direction or a width direction of the mask body 10. The curved portion 11 becomes closer to the mask area M that the curved portion 11 directly faces, from at least one end of the curved portion 11 to the middle of the curved portion 11.

It should be noted that, the edge extending along the preset stretching direction means that the edge, as a whole, extends substantially along the preset stretching direction. It should be understood that, hereinafter, two ends of the curved portion 11 refer to two ends of the curved portion 11 in the preset stretching direction, and the middle of the curved portion 11 refers to a center position between the two ends or a position near the center position.

It can be understood that, the above expression “the curved portion 11 recesses towards the mask area M that the curved portion 11 directly faces” means that a part from at least one end (e.g., a lower end) of the curved portion 11 to the middle of the curved portion 11 meets the following conditions: of any two positions in the part (e.g., position a and position b in the part between the lower end and the middle of the curved portion 11 as shown in FIG. 3), a vertical distance from one position (e.g., position a) closer to the middle of the curved portion 11 to a left edge of the mask area M is smaller than or equal to a vertical distance from the other position (e.g., position b) farther from the middle of the curved portion 11 to the left edge of the mask area M, and a vertical distance from the lower end of the curved portion 11 to the left edge of the mask area M is larger than a vertical distance from the middle of the curved portion 11 to the left edge of the mask area M. That is, the curved portion 11 is gradually closer to the mask area M from at least one end to the middle of the curved portion 11.

In the fabrication process of a mask, after the mask body 10 is formed, the mask body 10 is stretched to improve its structural stability, thereby obtaining the finally-required mask. In this case, pulling forces may be applied to the mask body 10 in the preset stretching direction. Because the curved portion 11 is gradually closer to the mask area M from at least one end to the middle of the curved portion 11, the pulling forces each will be decomposed into the following two parts when the mask body 10 is stretched in the preset stretching direction: one part for stretching the mask body 10 in the preset stretching direction, and the other part for allowing the areas on both sides of the mask area M to have the tendency to expand outward, thus alleviating the wrinkle phenomenon generated when stretching the mask body 10, and further improving the yield of display products fabricated using the stretched mask body.

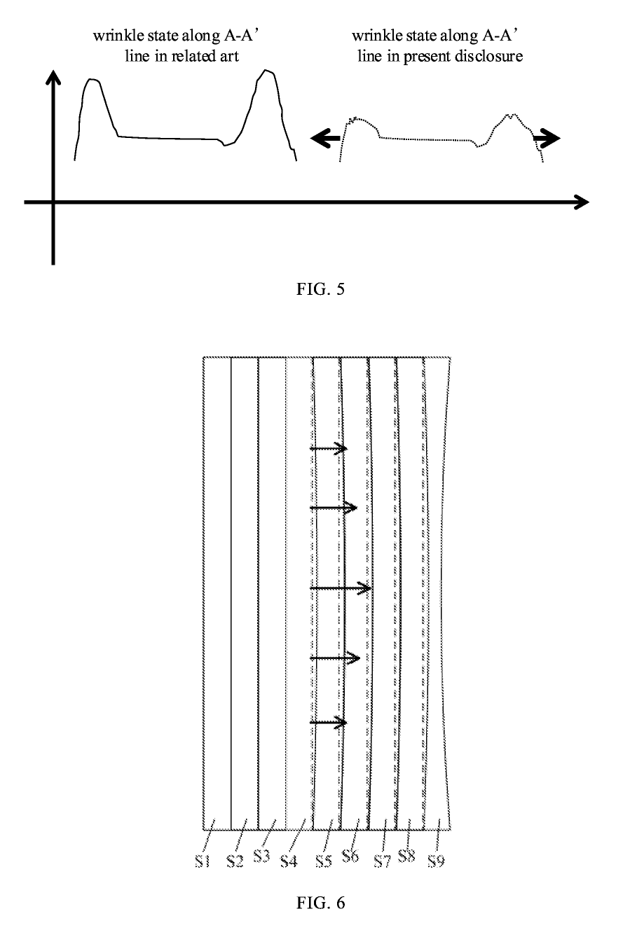

Optionally, the curved portion 11 gradually becomes closer to the mask area M from two ends to the middle of the curved portion 11 (as shown in FIG. 3), so that each position of the curved portion can have the tendency to expand outward (as shown by arrows pointing to left and right directions in FIG. 4). Furthermore, when stretching the mask body in the comparative example, the closer to the center of the mask area in the preset stretching direction, the more significant the wrinkle phenomenon. However, when the structure shown in FIG. 3 is adopted in the present disclosure, the closer to the middle of the curved portion 11 in the preset stretching direction, the more significant the expansion tendency (in FIG. 4, a black arrow with a longer length indicates a more significant expansion tendency). In this way, the wrinkle phenomenon of various degrees at different positions is alleviated. FIG. 5 is a comparison diagram illustrating wrinkle state along A-A′ line of the mask body shown in FIG. 4 of the present disclosure and subjected to stretching and wrinkle state along A-A′ line of the mask body shown in FIG. 1 of the comparative example and subjected to stretching. It can be seen that the wrinkled degree of the mask body 10 in the present disclosure that has been stretched is obviously less than the wrinkled degree of the mask body in the comparative example that has been stretched.

Optionally, the curved portion 11 becomes closer, in a stepwise manner, to the mask area M that the curved portion 11 directly faces, from two ends to the middle of the curved portion 11.

Optionally, the curved portion 11 has an arc shape bending towards the mask area M, so that the pulling forces transfer in the areas on both sides of the mask area M, which facilitates outward expansion of the portion on both sides of the mask area M.

A plurality of mask areas M may be provided in the mask body 10. In the case that the plurality of mask areas M are arranged in a direction perpendicular to the stretching direction, wrinkles are also likely to occur in a portion between two adjacent mask areas M. Thus, in order to reduce the occurrence of wrinkles, the plurality of mask areas M are arranged in the preset stretching direction, as shown in FIGS. 3 and 4.

A size of the mask area M in the preset stretching direction is in a range of 100 mm to 120 mm, in this case, a difference between a distance from any one end of the curved portion 11 to the mask area M and a distance from the middle of the curved portion 11 to the mask area M is in a range of 140 L μm to 160 L μm, and a distance from the middle of the curved portion 11 to the mask area M is in a range of 380 μm to 420 μm, where L is a value of shrinkage of the middle of an edge of a reference mask body corresponding to the mask body towards an inner side of the reference mask body when the reference mask body is stretched in the preset stretching direction. It should be noted that, the reference mask body refers to a mask body having a same size as the above-described mask body 10 provided in the present disclosure and a straight edge along the preset stretching direction, i.e., the mask body in the comparative example. In practical applications, a plurality of mask bodies (i.e., reference mask bodies) having straight edges may be first selected, and then stretched in the preset stretching direction, and subsequently, the sizes of inward shrinkage of the middle of the edges of the stretched reference mask bodies are detected, thus obtaining a value of L. A distance from two ends of the curved portion 11 to the mask area M refers to a vertical distance from the two ends of the curved portion 11 to the edge, extending along the preset stretching direction, of the mask area M, and a distance from the middle of the curved portion 11 to the mask area M refers to a vertical distance from the middle of the curved portion 11 to the edge, extending along the preset stretching direction, of the mask area M.

The mask body in the present disclosure is particularly applicable to a fine metal mask (FMM). Specifically, the mask body has a length in a range of 800 mm to 900 mm, a width in a range of 80 mm to 100 mm, and a thickness in a range of 20 μm to 40 μm. In this case, in the fabrication process of a mask, the mask body 10 is stretched in a length direction thereof, in order to facilitate application of pulling forces; accordingly, the preset stretching direction is the length direction of the mask.

Further, in order to make the mask body 10 have higher toughness and plasticity, in the present disclosure, a material for forming the mask body 10 includes invar. In this case, strength and structural stability of the mask body 10 can be improved by stretching.

Further, as shown in FIG. 3, in the preset stretching direction (the preset stretching direction is the length direction of the mask body 10 in FIG. 3), portions, on both sides of all the mask areas M, of the non-mask area NM of the mask body 10 each include: two extension parts 12 extending along the preset stretching direction and a connection part 13 connecting between the two extension parts 12, and the connection part 13 is connected to one end of each of the two extension parts 12 proximal to the mask area M. In the process of transporting the mask body 10, the extension part 12 is held by a clamping member so as to transport the mask body 10.

As another aspect of the present disclosure, there is provided a method for fabricating a mask, which includes the following steps.

Firstly, a mask body 10 is provided. The mask body 10 is the above-described mask body 10 including at least one mask area M and a non-mask area NM surrounding the at least one mask area M. A portion, directly facing the mask area M, of an edge extending along a preset stretching direction of the mask body 10 is formed as a curved portion 11. The curved portion 11 recesses towards the mask area M that the curved portion 11 directly faces.

Subsequently, outward pulling forces, which are along the preset stretching direction, are applied to two ends of the mask body 10 in the preset stretching direction, respectively. Optionally, the preset stretching direction is the length direction or width direction of the mask body 10. In an embodiment of the present disclosure, the mask body 10 has a length in a range of 800 mm to 900 mm, and a width in a range of 80 mm to 100 mm, and the preset stretching direction is the length direction of the mask body 10. As shown in FIG. 4, when the pulling forces are applied to stretch the mask body 10, the pulling forces at the two ends are respectively upward and downward along the length direction.

The method may further include: fixing the stretched mask body 10 to a frame to obtain the required mask. The mask may be put into an evaporation chamber for evaporation.

As described above, portions of the non-mask area NM of the mask body 10 on both sides of all the mask areas M in the preset stretching direction each include: two extension parts 12 extending along the preset stretching direction and a connection part 13 connecting between the two extension parts 12, and the connection part 13 is connected to one end of each of the two extension parts 12 proximal to the mask area M. In this case, when stretching the mask body 10, the pulling force is applied to one end of the extension part 12 distal to the mask area M.

In order to enable the tendency of outward expansion of the portions on both sides of the mask area M under the action of the pulling forces to reduce wrinkles, and prevent the pulling forces from being too large to deform or damage the mask, optionally, the pulling force applied to each end of the mask body 10 is gradually increased from a value of 1 N to 3 N to a value of 8 N to 12 N. For example, the pulling force at each end is increased from 2 N to 5 N, then increased to 7 N, and further increased to 10 N.

In the present disclosure, morphological changes of the mask body during fabrication are simulated by Ansys software. The mask body 10 is made of invar, has a length of 850 mm, a width of 85 mm and a thickness of 30 μm, and includes two mask areas M. A portion, directly facing a mask area M and extending along the preset stretching direction, of an edge of the mask body 10 is formed as a curved portion 11 having an arc shape, a distance from each of two ends of the curved portion 11 to the edge of the mask area is (400+150 L) μm, and a distance from the middle of the curved portion 11 to the edge of the mask area is 400 μm. Here, L is a size of inward shrinkage of the middle of an edge of a reference mask body when the reference mask body is stretched during fabrication. The reference mask body differs from the above mask body 10 of the present disclosure only in that the edge, extending along the preset stretching direction, of the reference mask body is straight, whereas the edge, extending along the preset stretching direction, of the above mask body 10 is formed with the above curved portion 11.

In simulation, only one-quarter portion 10a of the mask body 10 in FIG. 3 is simulated. After pulling forces of 10 N in total are applied to two ends of the portion, a result of state change of the one-quarter portion 10a of the mask body 10 is shown in FIG. 6. In simulation, in order to show expansion tendency of each portion of the mask body 10 more clearly, the one-quarter portion 10a of the mask body 10 is divided into a plurality of strip-shaped areas S1 to S9. Strip-shaped areas S1 to S7 correspond to the mask area of the one-quarter portion 10a of the mask body 10, and strip-shaped areas S8 to S9 correspond to the non-mask area of the one-quarter portion 10a of the mask body 10. Expansion tendencies of the respective areas of the one-quarter portion 10a of the mask body 10 are shown in FIG. 6, in which dotted lines represent original positions of the respective areas before stretching. It can be seen from FIG. 6 that, the expansion tendencies of areas S1 to S4 are less obvious, and the expansion tendencies of areas S5 to S9 are more obvious; the expansion tendency of upper and lower ends of each of the areas S5 to S9 is less obvious, and the expansion tendency of the middle of each of the areas S5 to S9 is more obvious. Because the wrinkled degrees of upper and lower ends of the one-quarter portion 10a of the mask body 10 are less than the wrinkled degree of the middle of the one-quarter portion 10a of the mask body 10 when the one-quarter portion 10a of the mask body 10 is stretched, wrinkle state at each position at both sides of the mask area can be improved after the mask body 10 is stretched in practical production.

As still another aspect of the present disclosure, there is provided a mask, which includes the above described mask body and a frame for mounting the mask body. In order to increase strength and stability of the mask body, the mask body may be stretched first, and the stretched mask body may be then fixed to the frame. It should be understood that, because a size of expansion of the mask body when being stretched is much smaller than the length and width of the mask body, for the size and shape of the mask body, reference may be made to the mask body 10 shown in FIG. 3.

It can be seen from the above description that, a portion, directly facing a mask area, of an edge extending along the preset stretching direction of the mask body provided in the present disclosure is formed as a curved portion, the curved portion recesses towards the mask area that the curved portion directly faces. Therefore, when the mask body is stretched in the preset stretching direction, the areas on both sides of the mask area are driven by stress to have the tendency to expand outward, thereby alleviating the wrinkle phenomenon in fabrication of the mask, and further improving the quality of a display substrate fabricated using the mask.

It could be understood that the above implementations are merely exemplary implementations adopted for describing the principle of the present disclosure, but the present disclosure is not limited thereto. Various variations and improvements may be made by those of ordinary skill in the art without departing from the spirit and essence of the present disclosure, and these variations and improvements shall also be regarded as falling into the protection scope of the present disclosure.

1. A mask body, comprising at least one mask area and a non-mask area surrounding the at least one mask area, wherein a portion, directly facing the mask area, of an edge, extending along a preset stretching direction, of the mask body is a curved portion, and the curved portion recesses towards the mask area that the curved portion directly faces.

2. The mask body of claim 1, wherein the preset stretching direction is a length direction or a width direction of the mask body.

3. The mask body of claim 1, wherein the curved portion becomes closer to the mask area that the curved portion directly faces, from two ends to the middle of the curved portion in the preset stretching direction.

4. The mask body of claim 3, wherein the curved portion is arc-shaped.

5. The mask body of claim 3, wherein the curved portion becomes closer, in a stepwise manner, to the mask area that the curved portion directly faces, from two ends to the middle of the curved portion in the preset stretching direction.

6. The mask body of claim 1, wherein the at least one mask area is arranged along the preset stretching direction.

7. The mask body of claim 2, wherein a size of the mask area in the preset stretching direction is in a range of 100 mm to 120 mm;
a difference between a distance from any one end of the curved portion to the mask area and a distance from the middle of the curved portion to the mask area is in a range of 140 L μm to 160 L μm, and the distance from the middle of the curved portion to the mask area is in a range of 380 μm to 420 μm, where L is a value of shrinkage of the middle of an edge of a reference mask body corresponding to the mask body towards an inner side of the reference mask body when the reference mask body is stretched in the preset stretching direction.

8. The mask body of claim 1, wherein the mask body has a length in a range of 800 mm to 900 mm, a width in a range of 80 mm to 100 mm, and a thickness in a range of 20 μm to 40 μm.

9. The mask body of claim 1, wherein a material for forming the mask body comprises invar.

10. The mask body of claim 1, wherein portions of the non-mask area on both sides of all of the at least one mask area in the preset stretching direction each comprise: two extension parts extending along the preset stretching direction and a connection part connecting between the two extension parts, and the connection part is connected to one end of each of the extension part proximal to the mask area.

11. A method for fabricating a mask, comprising:
providing a mask body, the mask body being the mask body of claim 1; and
applying pulling forces, which are along the preset stretching direction and towards an outer side of the mask body, to two ends of the mask body in the preset stretching direction, respectively.

12. The method of claim 11, wherein the pulling force applied to each end of the mask body is increased from a value ranging from 1 N to 3 N to a value ranging from 8 N to 12 N, gradually.

13. The method of claim 11, wherein portions of the non-mask area of the mask body on both sides of all of the at least one mask area in the preset stretching direction each comprise: two extension parts extending along the preset stretching direction and a connection part connecting between the two extension parts, and the pulling force is applied to one end of each of the extension part distal to the mask area.

14. The method of claim 11, further comprising fixing the stretched mask body to a frame to obtain the mask.

15. A mask, comprising the mask body of claim 1 and a frame for mounting the mask body.

16. The mask of claim 15, wherein the curved portion becomes closer to the mask area that the curved portion directly faces, from two ends to the middle of the curved portion in the preset stretching direction.

17. The mask of claim 16, wherein the curved portion is arc-shaped.

18. The mask of claim 16, wherein the curved portion becomes closer, in a stepwise manner, to the mask area that the curved portion directly faces, from two ends to the middle of the curved portion in the preset stretching direction.

19. The mask of claim 15, wherein the preset stretching direction is a length direction or a width direction of the mask body.

20. The mask of claim 15, wherein the at least one mask area is arranged along the preset stretching direction.
